(19) United States
(12) Patent Application Publication
(10) Pub. No.: US 2012/0161813 A1
(43) Pub. Date: Jun. 28, 2012

(54) SWITCH APPARATUS FOR FIELD PROGRAMMABLE GATE ARRAY

(75) Inventors: Han Jin CHO, Daejeon (KR); Young Hwan BAE, Daejeon (KR)

(73) Assignee: Electronics and Telecommunications Research Institute, Daejeon (KR)

(21) Appl. No.: 13/305,446

(22) Filed: Nov. 28, 2011

(30) Foreign Application Priority Data
Dec. 22, 2010 (KR) 10-2010-0132912

(51) Int. Cl. H03K 19/177

(52) U.S. Cl. 326/44; 326/39

(57) ABSTRACT

A switch apparatus of a Field Programmable Gate Array (FPGA) includes a pass transistor configured to switch and transfer an input signal to a logic cell according to a value of a configuration memory, and a voltage maintaining unit connected between the configuration memory and a gate of the pass transistor and configured to delay a drop of a gate voltage.

### CROSS-REFERENCE TO RELATED APPLICATIONS

The present application claims priority to Korean patent application number 10-2010-0132912, filed on Dec. 22, 2010, which is incorporated by reference in its entirety.

### BACKGROUND OF THE INVENTION

The present invention relates to a switch device of a Field Programmable Gate Array (FPGA), and more particularly, to a switch device of an FPGA capable of reducing a voltage drop which occurs when a signal passes through a switch device of an FPGA.

Generally, an FPGA is a kind of semi-custom logic integrated circuit. In comparison with a standard logic integrated circuit, the FPGA has the merits of short development time and low development cost.

That is, basic logic elements, i.e., gates, are arranged in parallel, a logic circuit is formed according to electrical wiring, and programming is made possible using millions of switches so that a logic integrated circuit required by a user is made.

Therefore, performance of a switch greatly influences overall performance of the FPGA.

FIG. 1 illustrates a circuit diagram of a basic cell of an FPGA to which a conventional Complementary Metal Oxide Semiconductor (CMOS) switch is applied, and FIG. 2 illustrates a circuit diagram of a basic cell of an FPGA to which a conventional N-type Metal Oxide Semiconductor (NMOS) transistor is applied.

As illustrated in FIG. 1, in the case of implementing a pass transistor with a CMOS switch 30 as an FPGA switch, a signal is transferred to a CMOS logic cell 20 according to a value of a configuration memory 10 so that an FPGA is operated.

In the case of adopting the CMOS switch 30 as described above, an area occupied by a switch becomes large. Moreover, an area needed for a P-type Metal Oxide Semiconductor (PMOS) transistor of the CMOS switch 30 is about two times larger than that of an NMOS transistor, and an inverter 32 for controlling a switch is additionally needed. Therefore, it has limitations to use the CMOS switch 30 for an FPGA where lots of switches are needed.

Therefore, for reducing an area of a switch, an NMOS transistor 40 is used as a pass transistor for an FPGA as illustrated in FIG. 2. In the case of using the NMOS transistor 40, an area is reduced by approximately 60% to 70% in comparison with using the CMOS switch 30.

In the case of using the NMOS transistor 40, it has no limitations to pass a low voltage GND; however, it has limitations to pass a high voltage VDD.

That is, due to characteristics of an NMOS transistor, a voltage is dropped as much as a threshold voltage Vth, and thus a voltage of VDD-Vth is passed through the NMOS transistor 40.

As a manufacturing process is developed to less than 0.5 μm process, the high voltage VDD is decreased to approximately 1V. However, the threshold voltage is not much decreased and still has a value of approximately 0.5V.

Therefore, since a voltage passed through the NMOS transistor 40 is approximately 0.5V, the CMOS logic cell 20 arranged at a following stage of the NMOS transistor 40 is weakly turned on causing a leakage current.

Further, the leakage current causes power loss increasing power consumption, and also causes malfunction.

The above-described technology does not mean a prior art but means a background of the technical field of the present invention.

### SUMMARY OF THE INVENTION

Embodiments of the present invention are directed to a switch apparatus of a low-power FPGA capable of reducing a voltage drop occurring at a switch by instantly increasing a gate voltage to more than a high voltage VDD using a capacitor component between a gate and drain/source of an NMOS transistor which is a switch of an FPGA.

In one embodiment, a switch apparatus of an FPGA includes: a pass transistor configured to switch and transfer an input signal to a logic cell according to a value of a configuration memory; and a voltage maintaining unit connected between the configuration memory and a gate of the pass transistor and configured to delay a drop of a gate voltage.

In the present invention, the pass transistor may be an NMOS transistor.

In the present invention, the voltage maintaining unit may be a resistor.

In the present invention, the voltage maintaining unit may be a bootstrap NMOS transistor.

### BRIEF DESCRIPTION OF THE DRAWINGS

FIG. 1 illustrates a circuit diagram of a basic cell of an FPGA to which a conventional CMOS switch is applied.

FIG. 2 illustrates a circuit diagram of a basic cell of an FPGA to which a conventional NMOS transistor is applied.

FIG. 3 illustrates a circuit diagram of a basic cell of an FPGA according to an embodiment of the present invention.

FIG. 4 illustrates a circuit diagram of a basic cell of an FPGA according to another embodiment of the present invention.

FIGS. 5 and 6 illustrate graphs of simulation results of the FPGA illustrated in FIG. 4.

FIG. 7 illustrates an exemplary diagram of a switch device of an FPGA according to an embodiment of the present invention.

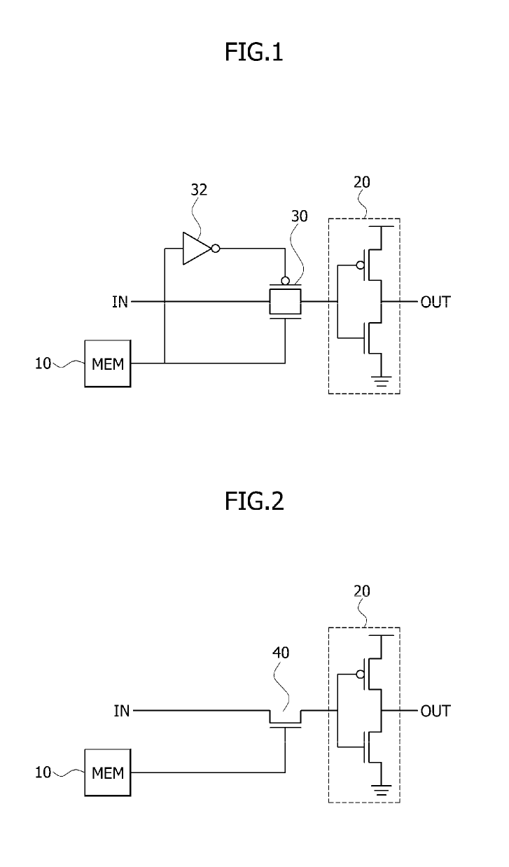

### DESCRIPTION OF SPECIFIC EMBODIMENTS

Hereinafter, a switch apparatus for a Field Programmable Gate Array (FPGA) in accordance with the present invention will be described in detail with reference to the accompanying drawings. In the drawings, line thicknesses or sizes of elements may be exaggerated for clarity and convenience. Also, the following terms are defined considering function of the present invention, and may be differently defined according to intention of an operator or custom. Therefore, the terms should be defined based on overall contents of the specification.

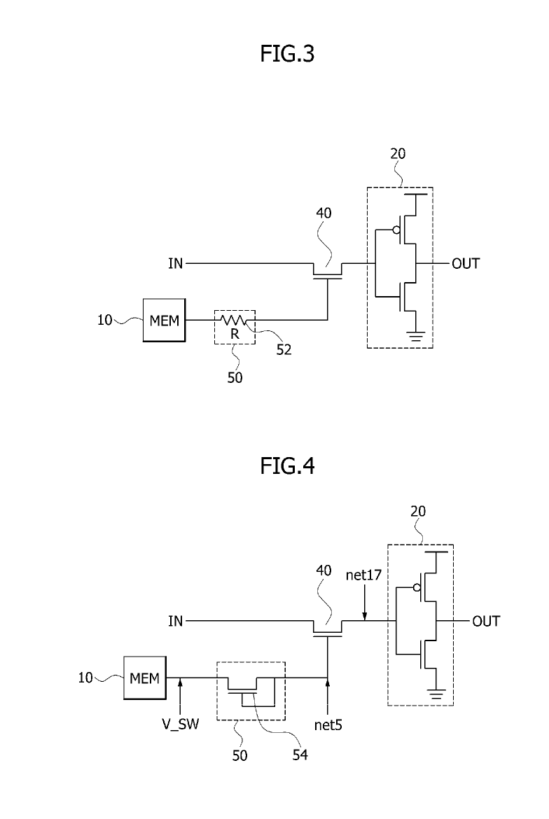

FIG. 3 illustrates a circuit diagram of a basic cell of an FPGA according to an embodiment of the present invention.

As illustrated in FIG. 3, the basic cell of an FPGA according to the embodiment of the present invention includes a pass transistor as a switch device for switching and transferring an input signal IN to a CMOS logic cell 20 according to a value of a configuration memory 10.

The switch device includes an NMOS transistor 40 turned on and turned off according to a value of the configuration memory 10, and a voltage maintaining unit 50 connected between a gate of the NMOS transistor 40 and an output terminal of the configuration memory 10 and configured to delay a voltage drop of the gate.

In FIG. 3, it is exemplarily illustrated that a resistor 52 is adopted for the voltage maintaining unit 50. Herein, resistance of the resistor 52 is sufficiently large such that an increased voltage is maintained until the CMOS logic cell 20 at a following stage is stabilized.

In the case of inserting the resistor 52 as the voltage maintaining unit 50 between the gate of the NMOS transistor 40 and the configuration memory 10 as described above, a variation value of an input signal IN increases a gate voltage of the NMOS transistor 40 because of a capacitance component between the gate and drain/source of the NMOS transistor 40, and thus the gate voltage is instantly increased to more than a high voltage VDD. Accordingly, a voltage of the input signal IN switched and passed through the NMOS transistor 40 is not dropped.

Therefore, a leakage current does not occur at the CMOS logic cell 20 connected to a following stage of the NMOS transistor 40, and thus a low-power FPGA may be implemented.

FIG. 4 illustrates a circuit diagram of a basic cell of an FPGA according to another embodiment of the present invention.

As illustrated in FIG. 4, a bootstrap NMOS transistor 54 is adopted for a voltage maintaining unit 50 of a switch device of an FPGA to delay a voltage drop of a gate.

As described above, the bootstrap NMOS transistor 54 instead of the resistor 52 is inserted to the voltage maintaining unit 50. Since a gate and a source are commonly coupled in the bootstrap NMOS transistor 54, there is an effect of a large resistance, and thus a voltage is maintained for a considerable time even after a gate voltage of the NMOS transistor 40 is instantly increased. Therefore, a voltage of an input signal IN switched and passed through is not dropped.

Therefore, a leakage current does not occur at the CMOS logic cell 20 connected to a following stage of the NMOS transistor 40, and thus a low-power FPGA may be implemented.

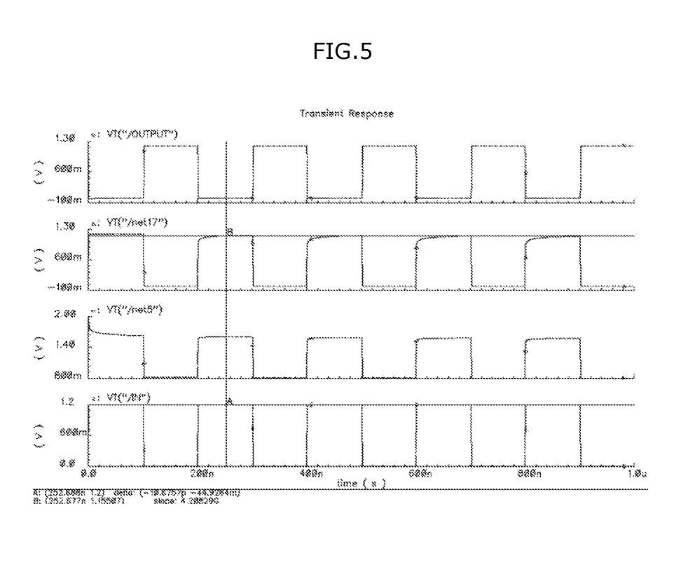

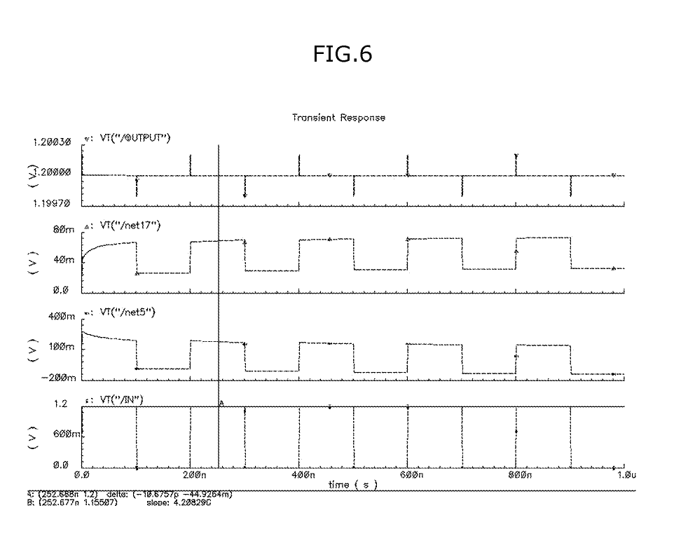

FIGS. 5 and 6 illustrate graphs of simulation results of the FPGA illustrated in FIG. 4. FIG. 5 illustrates a graph of a simulation result in the case of outputting VDD as an output value V_sw of the configuration memory 10. FIG. 6 illustrates a graph of a simulation result in the case of outputting GND as the output value V_sw of the configuration memory 10.

As illustrated in FIG. 5, in the case that VDD of approximately 1.2V is applied as the output value V_sw of the configuration memory 10, a gate (net5) voltage of the NMOS transistor 40 is increased to more than VDD. Also, when an input signal IN of approximately 1.2V is inputted, a voltage at a following stage (net17) of the NMOS transistor 40 is approximately 1.15507V, i.e., a voltage drop hardly occurs.

Meanwhile, as illustrated in FIG. 6, in the case that GND of approximately 0V is applied as the output value V_sw of the configuration memory 10, the gate (net5) voltage of the NMOS transistor 40 is approximately 200 mV so that the NMOS transistor 40 cannot be turned on. Accordingly, a voltage at the following stage (net17) of the NMOS transistor 40 is approximately 60 mV not passing the input signal IN.

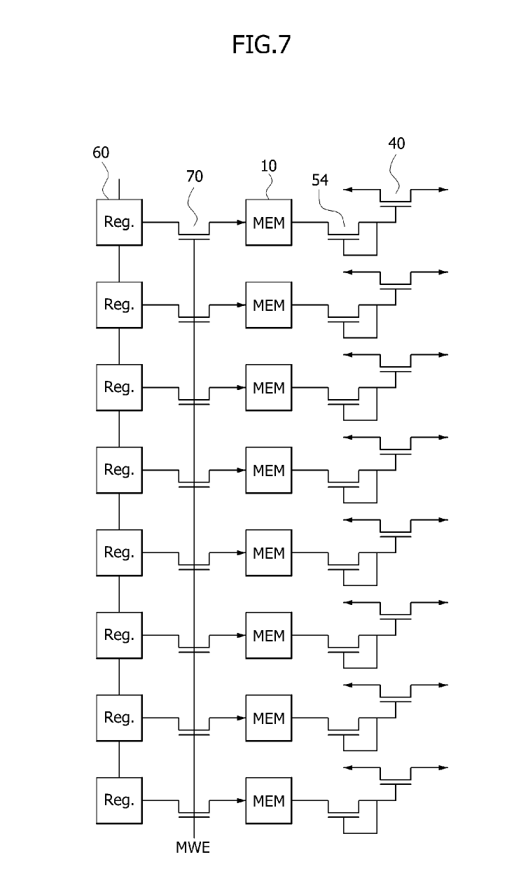

FIG. 7 illustrates an exemplary diagram of a switch device of an FPGA according to an embodiment of the present invention.

As illustrated in FIG. 7, the switch device may include a plurality of NMOS transistors 40 configured to respectively switch a plurality of input signals, a plurality of configuration memories 10 for the NMOS transistors 40, a plurality of bootstrap NMOS transistors 54 connected between the configuration memories 10 and gates of the NMOS transistors 40, a plurality of program registers 60 configured to store data for programming the configuration memories 10, and a plurality of programming transistors 70 configured to write data of the program registers 60 into the configuration memories 10.

For programming the NMOS transistor 40 in an FPGA, a voltage of VDD or GND is applied to a gate of the NMOS transistor 40 from the configuration memory 10.

Herein, a process for writing a determined value of VDD or GND into the configuration memory 10 is called FPGA programming. This value is shifted to the program register 60, and then recorded on the configuration memory 10 using the programming transistor 70.

Therefore, the value recorded on the configuration memory 10 is applied to a gate of the NMOS transistor 40, and thus the NMOS transistor 40 is accordingly turned on or off to transfer an input signal to the logic cell 20 at the following stage.

Meanwhile, by inserting the bootstrap NMOS transistor 54 which is the voltage maintaining unit 50 between the configuration memory 10 and a gate of the NMOS transistor 40, a voltage variation of a pass voltage increases a gate voltage using a capacitor between a gate and drain/source of the NMOS transistor 40 so that a voltage drop of a passing input signal may be reduced.

As described above, according to the present invention, a voltage drop occurring at a switch can be reduced by instantly increasing a gate voltage to more than a high voltage VDD using a capacitor component between a gate and drain/source of an NMOS transistor which is a switch of an FPGA. Therefore, power loss due to the voltage drop can be reduced, and malfunction can be prevented.

While the present invention has been described with respect to the specific embodiments, it will be apparent to those skilled in the art that various changes and modifications may be made without departing from the spirit and scope of the invention as defined in the following claims.

What is claimed is:

1. A switch apparatus of a Field Programmable Gate Array (FPGA), comprising:
a pass transistor configured to switch and transfer an input signal to a logic cell according to a value of a configuration memory; and
a voltage maintaining unit connected between the configuration memory and a gate of the pass transistor and configured to delay a drop of a gate voltage.

2. The switch apparatus of claim 1, wherein the pass transistor is an N-type Metal Oxide Semiconductor (NMOS) transistor.

3. The switch apparatus of claim 1, wherein the voltage maintaining unit is a resistor.

4. The switch apparatus of claim 1, wherein the voltage maintaining unit is a bootstrap transistor.
